(19) United States
(12) Patent Application Publication
(10) Pub. No.: US 2026/0129884 A1
(43) Pub. Date: May 7, 2026

(54) METAL-OXIDE-METAL (MOM) CAPACITOR

(71) Applicant: Microchip Technology Incorporated, Chandler, AZ (US)

(72) Inventors: Luke Anthony Johnson, Queen Creek, AZ (US); Fabien Vaucher, Lausanne (CH); Carlo Marino, Chandler, AZ (US); Mihai Claudiu Tanase, Bucharest (RO); Reiner Grimm, Ulm (DE); Jean-Michel Blin, Neu-Ulm (DE)

(73) Assignee: Microchip Technology Incorporated, Chandler, AZ (US)

(21) Appl. No.: 19/046,995

(22) Filed: Feb. 6, 2025

Related U.S. Application Data
(60) Provisional application No. 63/717,324, filed on Nov. 7, 2024.

(51) Int. Cl. H10D 1/66

(52) U.S. Cl. CPC H10D 1/66

(57) ABSTRACT

A capacitor may include a plurality of adjacent stacked layers and an atypical layer. Each of the plurality of adjacent stacked layers may include a first set of fingers. Each finger of the first sets of fingers may include a first end, a second end opposite the first end, and a body extending between the first and second ends in a first direction. The atypical layer may be disposed adjacent a first stacked layer of the plurality of stacked layers. The atypical layer may include a second set of fingers. Each finger of the second set of fingers may include a first end, a second end opposite the first end, and a body extending between the first and second ends in a second direction. The second direction may be substantially orthogonal to the first direction.

### CROSS-REFERENCE TO RELATED APPLICATIONS

The current patent application claims the benefit under 35 U.S. C. § 119(e) of the priority date of U.S. Provisional Application Ser. No. 63/717,324; titled “METAL-OXIDE-METAL (MOM) CAPACITOR”; and filed Nov. 7, 2024. The Provisional Application is hereby incorporated by reference, in its entirety, into the current patent application.

### TECHNICAL FIELD

Various examples of the present disclosure relate to a metal-oxide-metal (MOM) capacitor.

### BACKGROUND

Metal-oxide-metal (MOM) capacitors are typically designed to be as compact as possible within existing design constraints. Due to the design constraints, a top (or bottom) layer of a typical MOM capacitor may have different dimensions than the underlying layers. The top (or bottom) layer may be generally directionally aligned with the underlying layers and may be offset from underlying stacked layers due to the different dimensions. Due to the top (or bottom) layer being offset from the underlying layers, conductive vias (placed uniformly between the underlying stacked layers) may not be able to be placed between the top (or bottom layer) and the underlying stacked layers, thereby increasing an amount of space in, and lowering the overall capacitance of, the MOM capacitor.

This background discussion is intended to provide information related to the present invention which is not necessarily prior art.

### SUMMARY OF THE INVENTION

According to various examples of the present disclosure, a capacitor may include a plurality of adjacent stacked layers and an atypical layer. Each of the plurality of adjacent stacked layers may include a first set of fingers. Each finger of the first sets of fingers may include a first end, a second end opposite the first end, and a body extending between the first and second ends in a first direction. The atypical layer may be disposed adjacent a first stacked layer of the plurality of stacked layers. The atypical layer may include a second set of fingers. Each finger of the second set of fingers may include a first end, a second end opposite the first end, and a body extending between the first and second ends in a second direction. The second direction may be substantially orthogonal to the first direction.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates an elevated side view of an example MOM capacitor including a plurality of stacked layers and an atypical layer;

FIG. 2 illustrates a top view of one of the stacked layers of the MOM capacitor of FIG. 1;

FIG. 3 illustrates a top view of the atypical layer of the MOM capacitor of FIG. 1;

FIG. 4 illustrates the MOM capacitor of FIG. 1, rotated about a z-axis;

FIG. 5 illustrates a bottom perspective view of the MOM capacitor of FIG. 1;

FIG. 6 illustrates an elevated side view of an example two-by-two (2×2) MOM capacitor including a plurality of stacked layers and an atypical layer;

FIG. 7 illustrates a partial top view of one of the stacked layers of the 2×2 MOM capacitor of FIG. 6, omitting additional fingers of the stacked layer for clarity;

FIG. 8 illustrates a top view of the atypical layer of FIG. 6; and

FIG. 9 illustrates an elevated side view of the example 2×2 MOM capacitor of FIG. 6 with an additional, second atypical layer.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. While the drawings do not necessarily provide exact dimensions or tolerances for the illustrated components or structures, the drawings are to scale as examples of certain embodiments with respect to the relationships between the components of the structures illustrated in the drawings. Similar structures or components in the various drawings may retain the same or similar numbering for the convenience of the reader; however, the similarity in numbering does not mean that the structures or components are necessarily identical in size, composition, configuration, or any other property.

Furthermore, directional references (e.g., top, bottom, front, back, up, down, etc.) are used herein solely for the sake of convenience and should be understood only in relation to each other. For instance, a component might in practice be oriented such that faces referred to as “top” and “bottom”are sideways, angled, inverted, etc. relative to the chosen frame of reference.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Various examples of the present disclosure relate to a metal-oxide-metal (MOM) capacitor having an atypical orthogonal layer and a plurality of stacked layers. The plurality of stacked layers may be substantially the same. The atypical orthogonal layer may be orthogonal (i.e., rotated 90 degrees) relative to the underlying stacked layers. The orthogonality of the atypical layer may provide a compact design and increase the overall capacitance of the MOM capacitor.

As used herein, adjacent stacked layers may refer to two (2) stacked layers that face each other without any intervening layers. Accordingly, in various examples, a plurality of adjacent stacked layers may comprise two (2) or more substantially similar layers without any intervening atypical (i.e., rotated) layers. Similarly, adjacent fingers may be two (2) fingers of the same layer (e.g., having sides that face each other) without any intervening fingers.

As used herein, the term “substantially” may generally be used in reference to deviation beyond an industry-accepted range of manufacturing tolerances. For examples, two (2) fingers having “substantially” the same length may mean that the two (2) fingers have the same length within an industry-accepted range of manufacturing tolerance, typically determined by manufacturer(s) and/or standard setting industry and/or regulatory group(s) or agency(ies).

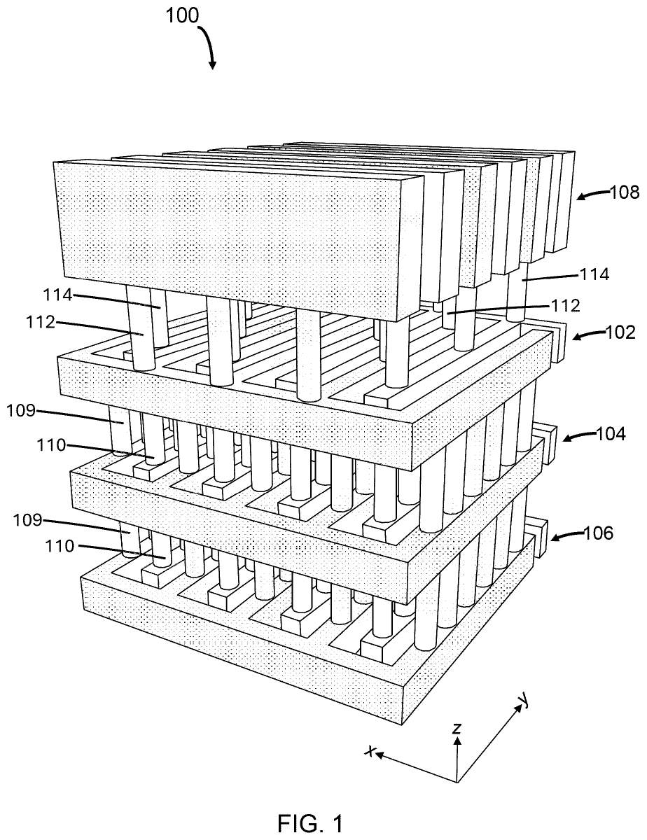

FIGS. 1-5 illustrate an example MOM capacitor 100. The MOM capacitor 100 includes a plurality of adjacent stacked layers including a stacked layer 102, a stacked layer 104, and a stacked layer 106. The MOM capacitor 100 also includes an orthogonal atypical layer 108. A first set of vias 109 and a second set of vias 110 connect the stacked layers 102, 104, 106 to each other. A third set of vias 112 and a fourth set of vias 114 connect the stacked layer 102 and the atypical layer 108. Each of the stacked layers 102, 104, 106 may be adjacent to one or more of the other stacked layers 102, 104, 106 and may be substantially identical to each other of the stacked layers 102, 104, 106.

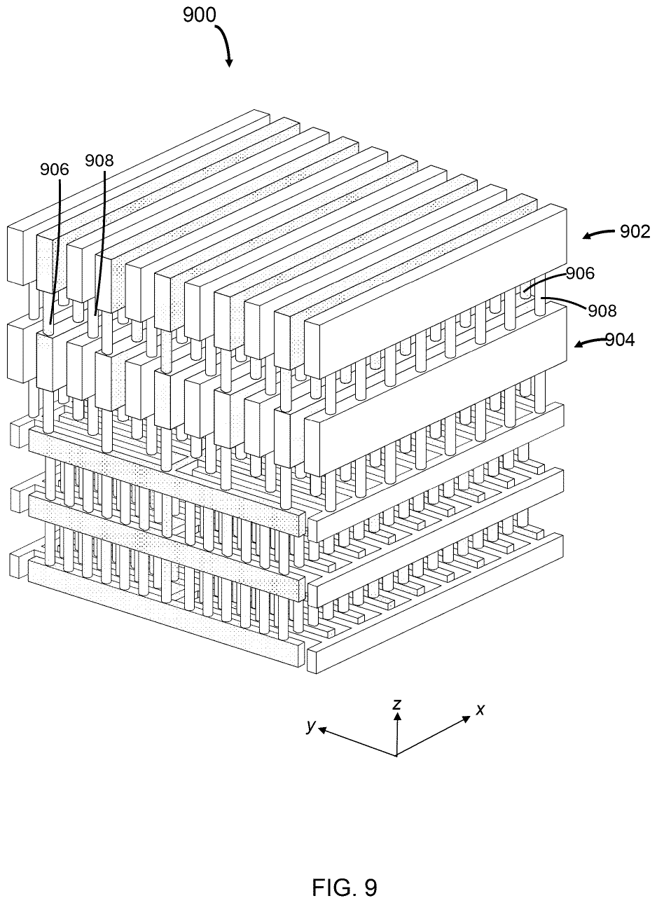

The stacked layer 102 may be either a top stacked layer or a bottom stacked layer. A “top” and “bottom” one of the stacked layers may be defined relative to an orientation of installation. For example, the bottom layer may be installed on a substrate and may contact the substrate, and the top layer may be opposite the bottom layer and may reside in a plane generally parallel to and offset from the substrate. Accordingly, the stacked layer 102 may be furthest from or closest to the substrate relative to the other(s) of the stacked layers 104, 106, with the atypical layer 108 correspondingly being adjacent the first stacked layer 102 opposite the other(s) of the stacked layers 104, 106. In various examples, the atypical layer 108 is either a top layer or a bottom layer of the MOM capacitor 100 (relative to all layers 102, 104, 106, 108), and/or is the penultimate top layer or bottom layer (e.g., where multiple atypical layers are included, as in FIG. 9).

In various examples, the vias 109, 110 may be integral with the corresponding stacked layers 102, 104, 106 and/or may be bonded to the corresponding stacked layers 102, 104, 106 by soldering, bonding, and/or another attachment means known to one of ordinary skill in the art. The vias 109, 110 may increase an overall capacitance of the MOM capacitor 100 by enabling electrical conductivity between adjacent stacked layers 102, 104, 106. Additionally, the vias 109, 110 may increase the overall capacitance of the MOM capacitor 100 due to their close proximity to adjacent vias 109, 110 within a same layer. Length(s) of the vias 109, 110 may define a distance between adjacent stacked layers 102, 104, 106. The length of each of the vias 109, 110 may be substantially the same between each pair of the adjacent stacked layers 102, 104, 106 or may be substantially the same between all pairs of adjacent stacked layers 102, 104, 106. Accordingly, the distance between adjacent stacked layers 102, 104, 106 may be the same. For example, a distance between the stacked layer 102 and the stacked layer 104 may be the same as a distance between the stacked layer 104 and the stacked layer 106.

In various examples, the vias 112, 114 may be integral to the stacked layer 102 and/or the atypical layer 108, and/or may be bonded to the stacked layer 102 and/or the atypical layer 108 by soldering, bonding, and/or another attachment means known to one of ordinary skill in the art. The vias 112, 114 may increase an overall capacitance of the MOM capacitor 100 by enabling electrical conductivity between the stacked layer 102 and the atypical layer 108. Additionally, the vias 112, 114 may increase the overall capacitance of the MOM capacitor 100 due to their close proximity to adjacent vias 112, 114 within a same layer.

In various examples, the vias 109 and the vias 112 may correspond to a first electrode (generally indicated by shading in FIGS. 1-5). The vias 110 and the vias 114 may correspond to a second electrode (generally indicated by a lack of shading in FIGS. 1-5). The first and second electrodes may have an opposite polarity. For example, the first electrode may be positively (+) charged, and the second electrode may be negatively (−) charged, or vice-versa.

The various components of the stacked layers (described below), the atypical layer (described below), and the vias described throughout this disclosure may be formed from an electrically conductive material and may include a number of metal layers, as is known to one of ordinary skill in the art.

In various examples a MOM capacitor may include an alternate polarity metal-oxide-metal (APMOM) capacitor, a vertical natural capacitor (VNCAP), and/or another type of MOM capacitor known to one of ordinary skill in the art.

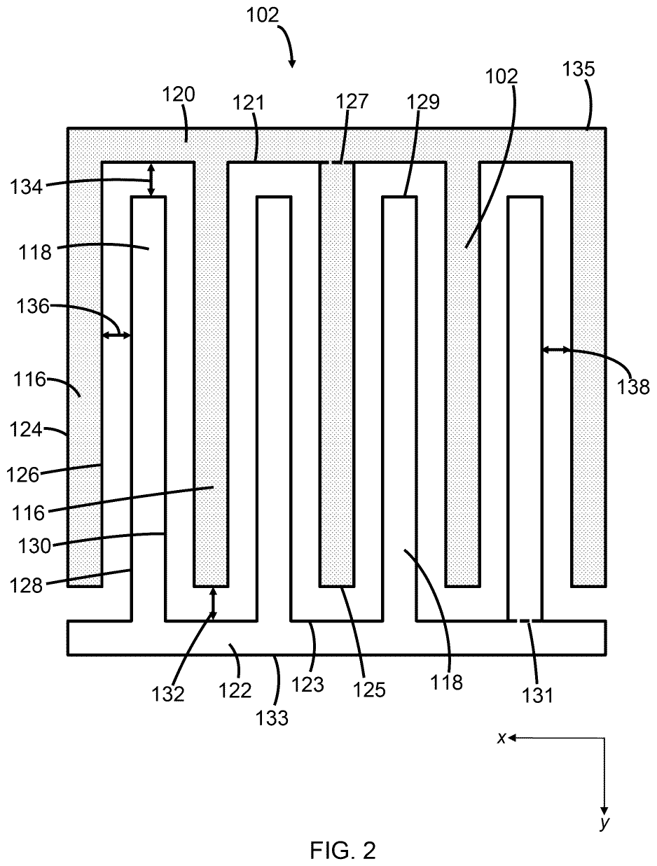

FIG. 2 illustrates the stacked layer 102. In various examples, each of the stacked layers 102, 104, 106 may be substantially identical. Accordingly, the illustration of FIG. 2 may represent any and/or all of the stacked layers 102, 104, 106. The stacked layer 102 may include a first finger subset comprising fingers 116, a second finger subset comprising fingers 118, a first sidewall 120, and a second sidewall 122.

The fingers 116 may be interdigitated with the fingers 118 such that each finger 116 may be adjacent one or more fingers of the fingers 118, and each finger 118 may be adjacent one or more of the fingers 116.

Each finger 116 of a first stacked layer of the stacked layers 102, 104, 106 may be positioned directly above or below a corresponding finger 116 of a second (adjacent) stacked layer of the stacked layers 102, 104, 106. Likewise, each finger 118 of the first stacked layer of the stacked layers 102, 104, 106 may be positioned directly above or below, as the case may be, a corresponding finger 118 of the second stacked layer of the stacked layers 102, 104, 106. Accordingly, the fingers 116 and the fingers 118 may have substantially the same positioning and alignment across the stacked layers 102, 104, 106, albeit displaced along an axis (e.g., a vertical or z-axis).

The fingers 116 of the first of the stacked layers 102, 104, 106, may be uniformly aligned with each other, and/or with the fingers 116 of each other of the stacked layers 102, 104, 106, along a first direction corresponding to an x-axis and a second direction corresponding to a y-axis. The fingers 118 of the first of the stacked layers 102, 104, 106, may be uniformly aligned with each other, and/or with the fingers 118 of each other of the stacked layers 102, 104, 106, along the first direction corresponding to the x-axis and the second direction corresponding to the y-axis. The fingers 116 and the fingers 118 of each stacked layer 102, 104, 106 may be uniformly aligned with each other, and/or with those fingers 116, 118 of each other of the stacked layers 102, 104, 106, along the x-axis and the y-axis.

The fingers 116 and the first sidewall 120 may correspond to the first electrode. Accordingly, the vias 109 may be connected to respective ones of the fingers 116 and/or the first sidewall 120. The vias 109 may connect the respective ones of the fingers 116 and/or the first sidewall 120 of one of the stacked layers 102, 104, 106 to the corresponding fingers 116 and/or first sidewall 120 of an adjacent one of the stacked layers 102, 104, 106.

The fingers 118 and the second sidewall 122 may correspond to the second electrode. Accordingly, the vias 110 may be connected to respective ones of the fingers 118 and/or the second sidewall 122. The vias 110 may connect the respective ones of the fingers 118 and/or the second sidewall 122 of one of the stacked layers 102, 104, 106 to the corresponding fingers 118 and/or second sidewall 122 of an adjacent one of the stacked layers 102, 104, 106.

Each finger 116 may include a first side 124, a second side 126, a first end 125, and a second end 127. Each finger 116 may include a body extending along the x-axis between the side 124 and the side 126 and extending along the y-axis between the end 125 and the end 127. Each finger 118 may include a first side 128, a second side 130, a first end 129, and a second end 131. Each finger 118 may include a body extending along the x-axis between the side 128 and the side 130 and extending along the y-axis between the end 129 and the end 131. The sidewall 120 may include an inner side 121 and an outer side 135. The sidewall 122 may include an inner side 123 and an outer side 133.

The fingers 116 may be integral and/or coupled to, and may extend substantially orthogonally from, the corresponding inner face 121 of the sidewall 120. The fingers 118 may be integral and/or coupled to, and may extend substantially orthogonally from, the corresponding inner face 123 of the sidewall 122.

Shortest distances (e.g., as illustrated, along the y-axis) between the first ends 125 of the fingers 116 and the inner side 123 of the sidewall 122 may define respective first sidewall gaps 132. Shortest distances (e.g., as illustrated, along the y-axis) between the first ends 129 of the fingers 118 and the inner side 121 of the sidewall 120 may define respective second sidewall gaps 134. The first sidewall gaps 132 and the second sidewall gaps 134 may be of consistent size across all fingers 116 of each layer 102, 104, 106, across all fingers 118 of each layer 102, 104, 106, and/or across all layers 102, 104, 106, and/or or may vary insubstantially within manufacturing tolerances within any of the foregoing groupings. Sizes (e.g., length, width) of the sidewall gaps 132, 134 may be substantially the same.

First finger gaps 136 may be defined as the distances between adjacent sides 126, 128 of corresponding pairs of fingers 116, 118. Second finger gaps 138 may be defined as the distances between adjacent sides 124, 130 of corresponding pairs of fingers 116, 118. The first finger gaps 136 and the second finger gaps 138 may be of consistent size across all fingers 116, 118 of each layer 102, 104, 106, and/or across all layers 102, 104, 106, and/or may vary insubstantially within manufacturing tolerances within any of the foregoing groupings. Sizes of the first and second finger gaps 136, 138 may be substantially the same.

The second ends 127, 131, illustrated using broken, fictitious lines in FIG. 2, may terminate or be defined at the junction with or the transition to the corresponding sidewall 120, 122, e.g., where the transition corresponds to a point at which surfaces of the sidewall 120, 122 and corresponding finger 116, 118 form a vertex of a right angle or a substantially right angle. In various examples, the second ends 127, 131 may be integral to the corresponding sidewall 120, 122 and/or may be coupled thereto by means of soldering, bonding, and/or other attachment means known to one of ordinary skill in the art.

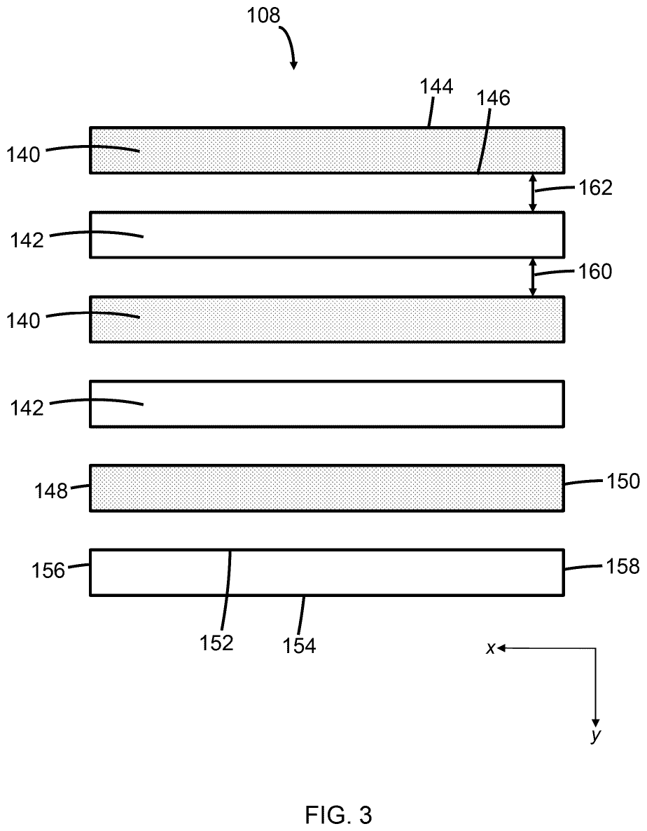

Turning to FIG. 3, the atypical layer 108 may include a first finger subset comprising fingers 140 and a second finger subset comprising fingers 142. The fingers 140 and the fingers 142 may be interleaved, such that each finger 140 may be adjacent one or more fingers 142, and each finger 142 may be adjacent one or more fingers 140.

In various examples, the fingers 140 may correspond to the first electrode. Accordingly, the vias 112 may be connected to corresponding fingers 140. The vias 112 may connect the fingers 140 to corresponding ones of the fingers 116 and/or the sidewall 120 of the stacked layer 102. The fingers 142 may correspond to the second electrode. Accordingly, the vias 114 may be connected to corresponding fingers 142. The vias 114 may connect the fingers 142 to the fingers 118 and/or the sidewall 122 of the stacked layer 102.

In various examples (not shown), the atypical layer may include two or more sidewalls respectively connecting the finger subsets of the atypical layer (i.e., analogous to the fingers 116 being connected by the sidewall 120 and the fingers 118 being connected by the sidewall 122, as illustrated in FIG. 2). In such examples, the ends and lengths of the fingers of the atypical layer may be defined in a similar manner as the fingers 116, 118 of the plurality of the stacked layers 102, 104, 106 illustrated in FIGS. 1-2 (i.e., where the length and body of each such finger extends from the juncture between the finger and the sidewall to which it is fixed and/or with which it is integral on the one hand, and the opposite end of the finger (which is free, or not fixed to or integral with a sidewall) on the other hand).

Each finger 140 includes a first side 144, a second side 146, a first end 148, and a second end 150. Each finger 140 includes a body extending between the first side 144 and the second side 146 along the y-axis and extending between the first end 148 and the second end 150 along the x-axis. Each finger 142 includes a first side 152, a second side 154, a first end 156, and a second end 158. Each finger 142 includes a body both extending between the first side 152 and the second side 154 along the y-axis and extending between the first end 156 and the second end 158 along the x-axis. The fingers 140 may be uniformly aligned with each other along the x-axis and the y-axis. The fingers 142 may be uniformly aligned with each other along the x-axis and the y-axis. The fingers 140, 142 may be uniformly aligned with each other along the x-axis and the y-axis.

First finger gaps 160 may be defined as the distances between adjacent sides 144, 154 of corresponding pairs of fingers 140, 142. Second finger gaps 162 may be defined as the distances between adjacent sides 146, 152 of corresponding pairs of fingers 140, 142. The finger gaps 160, 162 may be of consistent size across all fingers 140, 142 of the atypical layer 108 and/or may vary insubstantially within manufacturing tolerances within any of the foregoing groupings. Sizes of the first and second finger gaps 160, 162 may be substantially the same.

The sidewall gaps 132, 134, finger gaps 136, 138, and the finger gaps 160, 162 may be filled by a dielectric (e.g., air) and may be sized to have minimal distance(s) in accordance with design rules of the capacitor 100. In various examples, the finger gaps 160, 162 may be both larger than the finger gaps 136 and larger than the finger gaps 138. In alternative examples, the finger gaps 160, 162 may be both smaller than the finger gaps 136 and smaller than the finger gaps 138.

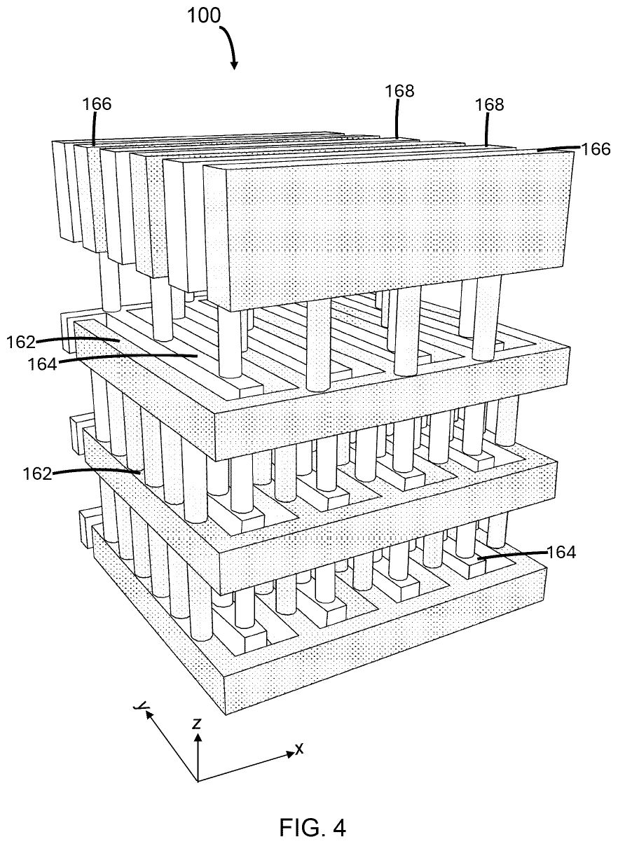

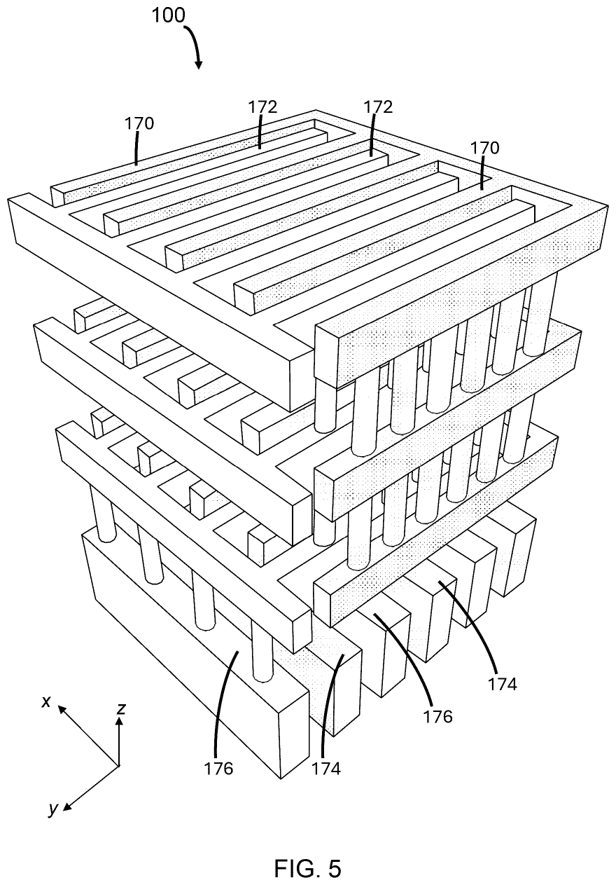

Turning to FIGS. 4 and 5, each finger 116 of each of the stacked layers 102, 104, 106 includes a top 162 (FIG. 4) and a bottom 170 (FIG. 5). Each finger 118 of each of the stacked layers 102, 104, 106 includes a top 164 (FIG. 4) and a bottom 172 (FIG. 5). Each finger 140 includes a top 166 (FIG. 4) and a bottom 170 (FIG. 5). Each finger 142 includes a top 168 (FIG. 4) and a bottom 176 (FIG. 5).

A distance between the top 162 of one of the fingers 116 on the one hand, and the corresponding bottom 170 of the finger 116 on the other hand, may define a thickness of the finger 116. A distance between the top 164 of one of the fingers 118 on the one hand, and the corresponding bottom 172 of the finger 118 on the other hand, may define a thickness of the finger 118. The thicknesses of the fingers 116, 118 may extend along the z-axis. In various examples, a thickness of each of the fingers 116, 118 may be defined as a maximum distance or span of the finger 116, 118 along the z-axis. The thickness of each finger 116 and the thickness of each finger 118 may be substantially the same.

Returning to FIGS. 2-3, a distance between the inner face 121 of the sidewall 120 at a junction with one of the fingers 116 (and/or the analogous second end 127) on the one hand, and the end 125 of the finger 116 on the other hand, may define a length of the finger 116. A distance between the inner face 123 of the sidewall 122 at a junction with one of the fingers 118 (and/or the analogous second end 131) on the one hand, and the end 129 of the finger 118 on the other hand, may define a length of the finger 118. The lengths of the fingers 116, 118 may extend along the y-axis. In various examples, a length of each of the fingers 116, 118 may be defined as a maximum distance or span of the fingers 116, 118 along the y-axis. The length of the fingers 116, 118 may be substantially the same.

A distance between the first side 124 of one of the fingers 116 on the one hand, and the second side 126 of the finger 116 on the other hand, may define a width of the finger 116. A distance between the first side 128 of one of the fingers 118 on the one hand and the second side 130 of the finger 118 may define a width of the finger 118. The width of the fingers 116, 118 may extend along the x-axis. In various examples, a width of each of the fingers 116, 118 may be defined as a maximum distance or span of the fingers 116, 118 along the x-axis. The width of the fingers 116, 118 may be substantially the same.

The length, width, and thickness of the fingers 116, 118 may be consistent within each stacked layer 102, 104, 106, across all fingers 116, 118, of all stacked layers 102, 104, 106, or may vary insubstantially within manufacturing tolerances within any of the foregoing groupings.

A distance between the top 166 of one of the fingers 140 on one hand, and the corresponding bottom 174 of the finger 140 on the other hand, may define a thickness of the finger 140. A distance between the top 168 of one of the fingers 142 on the one hand, and the corresponding bottom 176 of the finger 142 on the other hand, may define a thickness of the finger 142. The thickness of the fingers 140 and the fingers 142 may extend along the z-axis. In various examples, a thickness of each of the fingers 140, 142 may be defined as a maximum distance or span of the finger 140, 142 along the z-axis. The thickness of each finger 140 and the thickness of each finger 142 may be substantially the same.

A distance between the end 148 of one of the fingers 140 on the one hand, and the end 150 of the finger 140 on the other hand, may define a length of the finger 140. A distance between the end 156 one of the fingers 142 on the one hand, and the end 158 of the finger 142 on the other hand, may define a length of the finger 142. The lengths of the fingers 140, 142 may extend along the x-axis. In various examples, a length of each of the fingers 140, 142 may be defined as a maximum distance or span of the fingers 140, 142 along the x-axis. The length of the fingers 140, 142 may be substantially the same.

A distance between the first side 144 of one of the fingers 140 on the one hand, and the second side 146 of the finger 140 on the other hand, may define a width of the finger 140. A distance between the first side 152 one of the fingers 142 on the one hand, and the second side 154 of the finger 142 on the other hand, may define a width of the finger 142. The widths of the fingers 140, 142 may extend along the y-axis. In various examples, a width of each of the fingers 142, 142 may be defined as a maximum distance or span of the fingers 140, 142 along the y-axis. The width of the fingers 140, 142 may be substantially the same.

The length, width, and thickness of the fingers 140, 142 may be consistent within each atypical layer 108, across all fingers 140, 142 of all atypical layers 108, or may vary insubstantially within manufacturing tolerances within any of the foregoing groupings.

In various examples, the thickness of each of the fingers 140, 142 may be greater than the thickness of each of the fingers 116, 118. The length of each of the fingers 140, 142 may be greater than the length of each of the fingers 116, 118. The width of each the fingers 140, 142 may be greater than the width of each of the fingers 116, 118.

Each of the fingers 140, 142 (length extending along the x-axis) may be substantially orthogonal to each of the fingers 116, 118 (length extending along the y-axis). The orthogonality of the fingers 140, 142 relative to the fingers 116, 118 may optimize spacing constraints of the MOM capacitor 100 and increase the overall capacitance of the MOM capacitor 100 relative to designs having the top layer aligned with the stacked layers. Additionally, the orthogonality of the fingers 140, 142 relative to the fingers 116, 118 may enable efficient placement of the vias 112, 114 to connect the atypical layer 108 and the stacked layer 102, thereby further increasing the overall capacitance of the MOM capacitor 100.

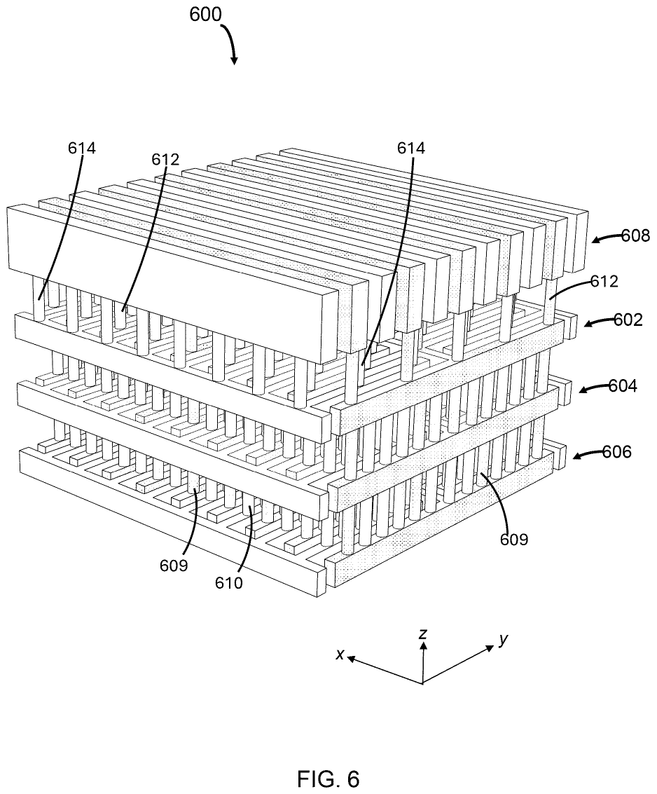

FIGS. 6-8 illustrate an example two-by-two (2×2) MOM capacitor 600. The MOM capacitor 600 may include a plurality of stacked layers including a stacked layer 602, a stacked layer 604, a stacked layer 606, and an orthogonal atypical layer 608. Each of the stacked layers 602, 604, 606, and the atypical layer 608 may be defined substantially similarly to analogous the stacked layers 102, 104, 106, and the atypical layer 108 discussed in more detail above in connection with FIGS. 1-5, except where described differently below.

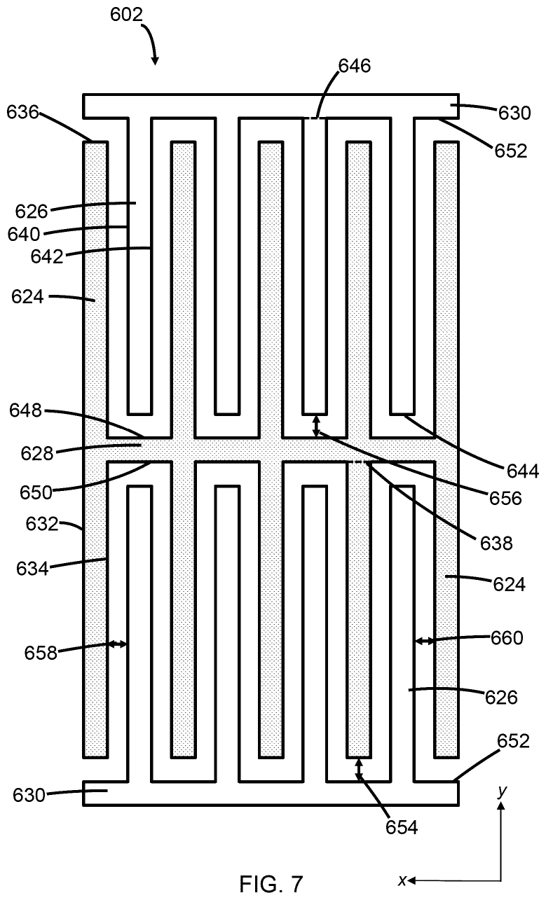

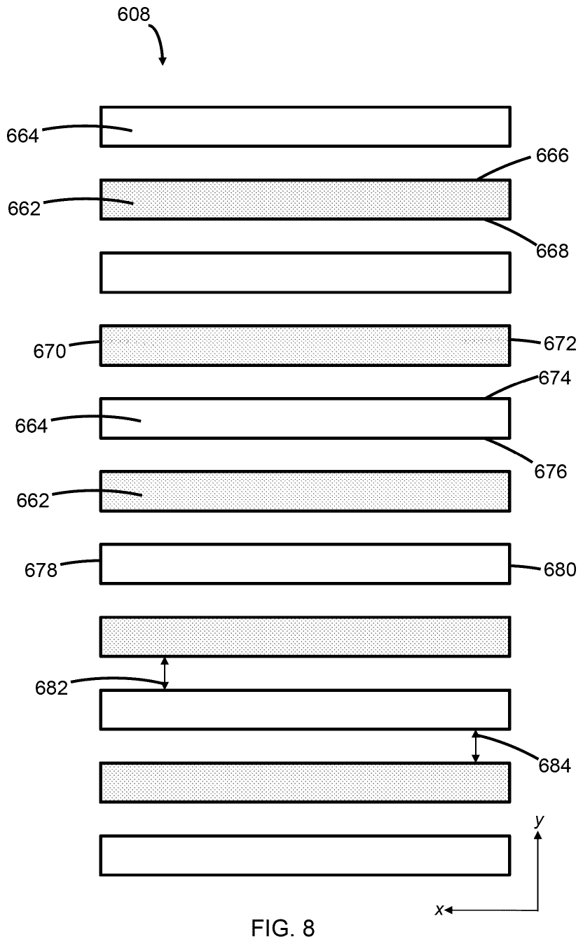

The length, width, thickness, and directionality of each of the fingers 624, 626 (FIG. 7), each of the fingers 662, 664 (FIG. 8), along with sidewall gaps 654, 656 (FIG. 7), finger gaps 658, 660 (FIG. 7), and finger gaps 682, 684 (FIG. 8), may be substantially the same as with analogous the fingers 116, 118, the fingers 140, 142, the sidewall gaps 132, 134, the finger gaps 136, 138, and the finger gaps 160, 162 described in connection with FIGS. 1-5, except where described differently below.

Turning to FIG. 6, a first set of vias 609 and a second set of vias 610 may may be defined substantially similarly to analogous vias 109, 110 described in connection with the examples of FIGS. 1-5, except that the number of vias 609, 610 may increase according to the increased number of fingers compared to the examples of FIGS. 1-5. A third set of vias 612 and a fourth set of vias 614 may be defined substantially similarly to analogous vias 112, 114 described in connection with the examples of FIGS. 1-5, except that the number of vias 612, 614 may increase according to the increased number of fingers compared to the examples of FIGS. 1-5.

FIG. 7 illustrates a partial top view of the stacked layer 602. The stacked layer 602 may include additional fingers that are not shown in FIG. 7 for clarity (but are shown in FIG. 6), but are added along either side of the components illustrated in FIG. 7 (that is, either side along the x-axis) using a simple extension of the component pattern and characteristics which are illustrated in FIG. 7 and described herein.

In various examples, each of the stacked layers 602, 604, 606 may be substantially identical. Accordingly, the illustration of FIG. 7 may represent a partial view of any and/or all of the stacked layers 602, 604, 606.

The stacked layer 602 may include a first finger subset comprising fingers 624, a second finger subset comprising fingers 626, a shared sidewall 628, and a pair of sidewalls 630.

The fingers 624 may each include a first side 632, a second side 634, a first end 636, and a second end 638. The fingers 626 may each include a first side 640, a second side 642, a first end 644, and a second end 646.

The shared sidewall 628 may include a first side 648 and a second side 650. The shared sidewall 628 may be defined substantially similarly to analogous sidewall 120 described in connection with FIGS. 1-5, except the shared sidewall 628 may be longer than the sidewall 120 (along the x-axis), may be connected to more fingers than the sidewall 120. Additionally, a first portion of the of the fingers 624 may be connected to the side 648 and a second portion of the fingers 624 may be connected to the second side 650. Each of the sidewalls 630 may be respectively defined substantially similarly to analogous sidewall 122 described in connection with FIGS. 1-5, except the sidewalls 630 may be longer (along the x-axis) and may be connected to more fingers than the sidewall 122, as shown in FIG. 6. Additionally, the MOM capacitor 600 includes a pair of sidewalls 630, whereas the MOM capacitor 100 includes one (1) sidewall 122.

The second ends 638, 646, illustrated using broken, fictitious lines in FIG. 7, may terminate or be defined at the junction with or the transition to the corresponding sidewall 628, 630, e.g., where the transition corresponds to a point at which surfaces of the sidewall 628, 630 and corresponding finger 624, 626 form a vertex of a right angle or a substantially right angle. In various examples, the second ends 638, 646 may be integral to the corresponding sidewall 628, 630 and/or may be coupled thereto by means of soldering, bonding, and/or other attachment means known to one of ordinary skill in the art.

Shortest distances (e.g., as illustrated, along the y-axis) between the first ends 636 of the fingers 624 and the inner side 652 of a corresponding closest one of the sidewalls 630 may define first sidewall gaps 654. Shortest distances (e.g., as illustrated, along the y-axis) between the first ends 644 of the fingers 626 and a corresponding closest one of the inner sides 648, 650 of the sidewall 628 may define second sidewall gaps 656. The first sidewall gaps 654 and the second sidewall gaps 656 may be of consistent size across all fingers 624 of each layer 602, 604, 606, across all fingers 626 of each layer 602, 604, 606, and/or across all layers 602, 604, 606, and/or may vary insubstantially within manufacturing tolerances within any of the foregoing groupings. A size (e.g., length, width) of the sidewall gaps 654, 656 may be substantially the same.

First finger gaps 658 may be defined as the distances between adjacent sides 634, 640 of corresponding pairs of fingers 624, 626. Second finger gaps 660 may be defined as the distances between adjacent sides 632, 642 of corresponding pairs of fingers 624, 626. The first finger gaps 658 and the second finger gaps 660 may be of consistent size across all fingers 624, 626 of each layer 602, 604, 606, and/or across all layers 602, 604, 606, and/or may vary insubstantially within manufacturing tolerances within any of the foregoing groupings. Sizes of the first and second finger gaps 658, 660 may be substantially the same.

A distance between an end 636 of a finger 624 on the one hand, and a respective (closest) one of the inner faces 648, 650 of the sidewall 628 at a junction with the finger 624 (and/or the analogous second end 638) on the other hand, may define a length of the finger 624.

A distance between an end 644 of a finger 626 on the one hand, and the inner face 652 of the corresponding (closest) sidewall 630 at a junction with the finger 626 (and/or the analogous second end 646) on the other hand, may define a length of the finger 626.

The lengths of the fingers 624, 626 may extend along the y-axis. In various examples, a length of each of the fingers 624, 626 may be defined as a maximum distance or span of the finger 624, 626 along the y-axis. The length of the fingers 624, 626 may be substantially the same.

A distance between the first side 632 of one of the fingers 624 on the one hand, and the second side 634 of the finger 624 on the other hand, may define a width of the finger 624. A distance between the first side 640 of one of the fingers 626 on the one hand, and the second side 642 of the finger 626 on the other hand, may define a width of the finger 626. The widths of the fingers 624, 626 may extend along the x-axis. In various examples, a width of each of the fingers 624, 626 may be defined as a maximum distance or span of the finger 624, 626 along the x-axis. The widths of the fingers 624, 626 may be substantially the same.

A distance between a top of one of the fingers 624 on the one hand, and a bottom of the finger 624 on the other hand, may define a thickness of the finger 624. Although not shown in FIGS. 6-8, the top and bottom of each of the fingers 624 may be defined substantially similarly to analogous top 162 and bottom 170 of the fingers 116 described with reference to FIGS. 1-5. A distance between a top of one of the fingers 626 on the one hand, and a bottom of the finger 626 on the other hand, may define a thickness of the finger 626. Although not shown in FIGS. 6-8, the top and bottom of each of the fingers 626 may be defined substantially similarly to analogous top 164 and bottom 172 of the fingers 118 described with reference to FIGS. 1-5.

The length, width, and thickness of the fingers 624, 626 may be consistent within each stacked layer 602, 604, 606, across all fingers 624, 626, of all stacked layers 602, 604, 606, or may vary insubstantially within manufacturing tolerances within any of the foregoing groupings.

FIG. 8 illustrates a top view of the atypical layer 608. The atypical layer 608 may include a first finger subset comprising fingers 662 and a second finger subset comprising fingers 664. Each of the fingers 662 may include a first side 666, a second side 668, a first end 670, and a second end 672. Each of the fingers 664 may include a first side 674, a second side 676, a first end 678, and a second end 680.

First finger gaps 682 may be defined as the distances between adjacent sides 668, 674 of corresponding pairs of fingers 662, 664. Second finger gaps 684 may be defined as the distances between adjacent sides 666, 662 of corresponding pairs of fingers 662, 664.

A distance between the end 670 of one of the fingers 662 on the one hand, and the end 672 of the finger 662 on the other hand, may define a length of the finger 662. A distance between the end 678 one of the fingers 664 on the one hand, and the end 680 of the finger 664 on the other hand, may define a length of the finger 664. The lengths of the fingers 662, 664 may extend along the x-axis. In various examples, a length of each of the fingers 662, 664 may be defined as a maximum distance or span of the finger 662, 664 along the x-axis. The length of the fingers 662, 664 may be substantially the same.

A distance between the first side 666 of one of the fingers 662 on the one hand, and the second side 668 of the finger 662 on the other hand, may define a width of the finger 662. A distance between the first side 674 one of the fingers 664 on the one hand, and the second side 676 of the finger 664 on the other hand, may define a width of the finger 664. The widths of the fingers 662, 664 may extend along the y-axis. In various examples, a width of each of the fingers 664, 664 may be defined as a maximum distance or span of the finger 662, 664 along the y-axis. The width of the fingers 662, 664 may be substantially the same.

A distance between a top of one of the fingers 662 on the one hand, and a bottom of the finger 662 on the other hand, may define a thickness of the finger 662. Although not shown in FIGS. 6-8, the top and bottom of each of the fingers 662 may be defined substantially similarly to analogous top 166 and bottom 174 of the fingers 140 described with reference to FIGS. 1-5. A distance between a top of one of the fingers 664 on the one hand, and a bottom of the finger 664 on the other hand, may define a thickness of the finger 664. Although not shown in FIGS. 6-8, the top and bottom of each of the fingers 664 may be defined substantially similarly to analogous top 168 and bottom 176 of the fingers 142 described with reference to FIGS. 1-5.

The length, width, and thickness of the fingers 662, 664 may be consistent within each atypical layer 608, across all fingers 662, 664 of all atypical layers 608, or may vary insubstantially within manufacturing tolerances within any of the foregoing groupings.

In various examples, the thickness of each of the fingers 662, 664 may be greater than the thickness of each of the fingers 624, 626. The length of each of the fingers 662, 664 may be greater than the length of each of the fingers 624, 626. The width of each the fingers 662, 664 may be greater than the width of each of the fingers 624, 626.

Each of the fingers 662, 664 (length extending along the x-axis) may be substantially orthogonal to each of the fingers 624, 626 (length extending along the y-axis). The orthogonality of the fingers 662, 664 relative to the fingers 624, 626 may optimize spacing constraints of the MOM capacitor 600 and increase the overall capacitance of the MOM capacitor 600 relative to designs having the top layer aligned with the stacked layers. Additionally, the orthogonality of the fingers 662, 664 relative to the fingers 624, 626 may enable efficient placement of the vias 612, 614 to connect the atypical layer 608 and the stacked layer 602, thereby further increasing the overall capacitance of the MOM capacitor 600.

FIG. 9 illustrates an elevated perspective view of a MOM capacitor 900. The MOM capacitor 900 may be substantially identical to the MOM capacitor 600, except for the addition of a second atypical layer 902. The second atypical layer 902 may be adjacent a first atypical layer 904. The first atypical layer 904 may be defined substantially similarly to analogous atypical layer 608 described in connection with FIGS. 6 and 8. The second atypical layer 902 may be defined substantially similarly to analogous atypical layer 608 described in connection with FIGS. 6 and 8, except that the second atypical layer 902 is added and adjacent to the first atypical layer 904. A first set of vias 906 and a second set of vias 908 may connect the second atypical layer 902 and the atypical layer 904. The vias 906, 908 may be defined substantially similarly to analogous vias 612, 614 described in connection with FIG. 6, except that the vias 906, 908 may connect the adjacent atypical layers 902, 904 to each other (rather than connecting an atypical layer to one of the stacked layers).

In various examples, the second atypical layer 902 may include a set of fingers. The set of fingers of the second atypical layer 902 may be substantially aligned with the fingers of the first atypical layer 904. In various examples, the fingers of the atypical layers 902, 904 are aligned in a first direction corresponding to an x-axis and in a second direction corresponding to a y-axis. In various examples, the second atypical layer 902 may be substantially identical to the first atypical layer 904. In various examples, a second atypical layer may be disposed either directly below a first atypical layer or directly above the first atypical layer, without limitation.

According to various examples of the present disclosure, a capacitor may include a plurality of adjacent stacked layers and an atypical layer. Each of the plurality of adjacent stacked layers may include a first set of fingers. Each finger of the first sets of fingers may include a first end, a second end opposite the first end, and a body extending between the first and second ends in a first direction. The atypical layer may be disposed adjacent a first stacked layer of the plurality of stacked layers. The atypical layer may include a second set of fingers. Each finger of the second set of fingers may include a first end, a second end opposite the first end, and a body extending between the first and second ends in a second direction. The second direction may be substantially orthogonal to the first direction.

In combination with any of the previous examples, a distance between adjacent fingers of each of first sets of fingers may define corresponding first finger gaps. A distance between adjacent fingers of a second set of fingers may define corresponding second finger gaps. Each of the second finger gaps may be larger than each of the first finger gaps.

In combination with any of the previous examples, a first length of each finger of first sets of fingers may be substantially the same. A second length of each finger of a second set of fingers may be substantially the same. A first width of each finger of the first sets of fingers may be smaller than a second width of each finger of the second set of fingers.

In combination with any of the previous examples, a first stacked layer may be a bottom layer of a plurality of stacked layers.

In combination with any of the previous examples, a first stacked layer may be a top layer of a plurality of stacked layers.

In combination with any of the previous examples, a first thickness of each finger of first sets of fingers may be smaller than a second thickness of each finger of a second set of fingers.

In combination with any of the previous examples, a capacitor may include a first set of vias coupled between adjacent stacked layers. A second set of vias may be coupled between a first stacked layer and an atypical layer. The first and second set of vias may be operable to increase a capacitance of the capacitor.

In combination with any of the previous examples, each finger of first sets of fingers may present a first side and a second side opposite the first side. Each of a first set of vias may be coupled to the first side of one of the fingers of the first sets of fingers and to the second side of an other of the fingers of the first sets of fingers. The other of the fingers may be in an adjacent one of a plurality of stacked layers.

In combination with any of the previous examples, each finger of a first set of fingers of a first stacked layer may present a first side and a second side opposite the first side. Each finger of a second set of fingers may present a first side and a second side opposite the first side.

In combination with any of the previous examples, each via of a second set of vias may be coupled to a first side of a finger of a first set of fingers of a first stacked layer and to a second side of a finger of a second set of fingers.

In combination with any of the previous examples, each of a plurality of first sets of fingers and a second set of fingers may include a first finger subset corresponding to a first electrode and a second finger subset corresponding to a second electrode. Each subset of the first finger subsets of the first sets of fingers may be interdigitated with a corresponding subset of the second finger subsets of the first sets of fingers. The first finger subset of the second set of fingers may be interleaved with the second finger subset of the second set of fingers.

In combination with any of the previous examples, each of a plurality of stacked layers may include a first sidewall and a second sidewall opposite the first side wall. Each of the first and second sidewalls may present an inner face. A first end of each finger of a first finger subset may terminate at the inner face of the corresponding first sidewall. A second end of each finger of the first finger subset may be adjacent the inner face of the corresponding second sidewall to define respective first sidewall gaps. A first end of each finger of a second finger subset may terminate at the inner face of the corresponding second sidewall. A second end of each finger of the second finger subset may be adjacent the inner face of the corresponding first sidewall to define respective second sidewall gaps.

In combination with any of the previous examples, a capacitor may include a second atypical layer adjacent an atypical layer opposite a first stacked layer. The second atypical layer may include a third set of fingers. Each finger of the third set of fingers may present a first end, a second end opposite the first end, and a body extending along a second direction between the first and second ends.

In combination with any of the previous examples, a first length of each finger of a plurality of first sets of fingers may be substantially the same. A second length of each finger of a second set of fingers and a third length of each finger of a third set of fingers may be substantially the same. A first width of each finger of the first sets of fingers may be both smaller than a second width of each finger of the second set of fingers and smaller than a third width of each finger of the third set of fingers. The second and third widths may be substantially the same. A first thickness of each finger of the first sets of fingers may be both smaller than a second thickness of each finger of the second set of fingers and smaller than a third thickness of each finger of the third set of fingers. The second and third thicknesses may be substantially the same.

In combination with any of the previous examples, a set of vias may be coupled between an atypical layer and a second atypical layer. The set of vias may be operable to increase a capacitance of a capacitor.

In combination with any of the previous examples, each finger of a second set of fingers and each finger of a third set of fingers may present a first side and a second side opposite the first side. Each via of a set of vias may be coupled to the first side of one of the fingers of the second set of fingers and to the second side of one of the fingers of the third set of fingers.

In combination with any of the previous examples, each finger of a second set of fingers and each finger of a third set of fingers may include a first finger subset corresponding to a first electrode and a finger subset corresponding to a second electrode. The fingers of each of the first finger subsets may be interleaved with a corresponding subset of the second finger subsets.

In combination with any of the previous examples, a distance between adjacent fingers of each of first sets of fingers may define corresponding first finger gaps. A distance between adjacent fingers of a second set of fingers may define corresponding second finger gaps. A distance between adjacent fingers of a third set of fingers may define corresponding third finger gaps. Each of the second finger gaps and the third finger gaps may be larger than each of the first finger gaps.

In combination with any of the previous examples, a capacitor may be one of a MOM capacitor, an APMOM capacitor, and a VNCAP.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for”or “step for”language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A capacitor comprising:
a plurality of adjacent stacked layers, each of the plurality of adjacent stacked layers including a first set of fingers, each finger of the first sets of fingers having a first end, a second end opposite the first end, and a body extending between the first and second ends in a first direction; and
an atypical layer disposed adjacent a first stacked layer of the plurality of stacked layers, the atypical layer including a second set of fingers, each finger of the second set of fingers having a first end, a second end opposite the first end, and a body extending between the first and second ends in a second direction, the second direction being substantially orthogonal to the first direction.

2. The capacitor of claim 1,
a distance between adjacent fingers of each of the first sets of fingers defining corresponding first finger gaps,
a distance between adjacent fingers of the second set of fingers defining corresponding second finger gaps,
each of the second finger gaps being larger than each of the first finger gaps.

3. The capacitor of claim 1,
a first length of each finger of the first sets of fingers being substantially the same,
a second length of each finger of the second set of fingers being substantially the same,
a first width of each finger of the first sets of fingers being smaller than a second width of each finger of the second set of fingers.

4. The capacitor of claim 1,
the first stacked layer being a bottom layer of the plurality of stacked layers.

5. The capacitor of claim 1,
the first stacked layer being a top layer of the plurality of stacked layers.

6. The capacitor of claim 1,
a first thickness of each finger of the first sets of fingers being smaller than a second thickness of each finger of the second set of fingers.

7. The capacitor of claim 1, comprising:
a first set of vias coupled between adjacent ones of the plurality of stacked layers,
a second set of vias coupled between the first stacked layer and the atypical layer,
the first and second sets of vias being operable to increase a capacitance of the capacitor.

8. The capacitor of claim 7,
each finger of the first sets of fingers presenting a first side and a second side opposite the first side,
each of the first set of vias being coupled to the first side of one of the fingers of the first sets of fingers and to the second side of an other of the fingers of the first sets of fingers, the other of the fingers being in an adjacent one of the plurality of stacked layers.

9. The capacitor of claim 7,
each finger of the first set of fingers of the first stacked layer presenting a first side and a second side opposite the first side,
each finger of the second set of fingers presenting a first side and a second side opposite the first side.

10. The capacitor of claim 9,
each via of the second set of vias being coupled to the first side of one of the fingers of the first set of fingers of the first stacked layer and to the second side of one of the second set of fingers.

11. The capacitor of claim 1,
each of the first sets of fingers and the second set of fingers including a first finger subset corresponding to a first electrode and a second finger subset corresponding to a second electrode,
each subset of the first finger subsets of the first sets of fingers being interdigitated with a corresponding subset of the second finger subsets of the first sets of fingers,
the first finger subset of the second set of fingers being interleaved with the second finger subset of the second set of fingers.

12. The capacitor of claim 11,
each of the plurality of stacked layers including a first sidewall and a second sidewall opposite the first sidewall,
each of the first and second sidewalls presenting an inner face,
the first end of each of the fingers of the first finger subsets terminating at the inner face of the corresponding first sidewall,
the second end of each of the fingers of the first finger subsets being adjacent the inner face of the corresponding second sidewall to define respective first sidewall gaps,
the first end of each of the fingers of the second finger subsets terminating at the inner face of the corresponding second sidewall,
the second end of each of the fingers of the second finger subsets being adjacent the inner face of the corresponding first sidewall to define respective second sidewall gaps.

13. The capacitor of claim 1, comprising:
a second atypical layer adjacent the atypical layer opposite the first stacked layer, the second atypical layer including a third set of fingers, each finger of the third set of fingers presenting a first end, a second end opposite the first end, and a body extending along the second direction between the first and second ends.

14. The capacitor of claim 13,
a first length of each finger of the first sets of fingers being substantially the same,
a second length of each finger of the second set of fingers and a third length of each finger of the third set of fingers being substantially the same,
a first width of each finger of the first sets of fingers being both smaller than a second width of each finger of the second set of fingers and smaller than a third width of each finger of the third set of fingers,
the second and third widths being substantially the same,
a first thickness of each finger of the first sets of fingers being both smaller than a second thickness of each finger of the second set of fingers and smaller than a third thickness of each finger of the third set of fingers,
the second and third thicknesses being substantially the same.

15. The capacitor of claim 13,
a set of vias coupled between the atypical layer and the second atypical layer,
the set of vias being operable to increase a capacitance of the capacitor.

16. The capacitor of claim 15,
each finger of the second set of fingers and each finger of the third set of fingers presenting a first side and a second side opposite the first side,
each via of the set of vias being coupled to the first side of one of the fingers of the second set of fingers and to the second side of one of the fingers of the third set of fingers.

17. The capacitor of claim 13,
each finger of the second set of fingers and each finger of the third set of fingers including a first finger corresponding to a first electrode and a second finger subset corresponding to a second electrode,
each subset of the first finger subsets being interleaved with a corresponding subset of the second finger subsets.

18. The capacitor of claim 13,
a distance between adjacent fingers of each of the first sets of fingers defining corresponding first finger gaps,
a distance between adjacent fingers of the second set of fingers defining corresponding second finger gaps,
a distance between adjacent fingers of the third set of fingers defining corresponding third finger gaps,
each of the second finger gaps and the third finger gaps being larger than each of the first finger gaps.

19. The capacitor of claim 1,
wherein the capacitor is one of: a metal-oxide-metal (MOM) capacitor, an alternate polarity metal-oxide-metal (APMOM) capacitor, and a vertical natural capacitor (VNCAP).
